(19) United States
(12) Patent Application Publication
(10) Pub. No.: US 2013/0109123 A1
(43) Pub. Date: May 2, 2013

(54) DIFFUSING AGENT COMPOSITION AND METHOD OF FORMING IMPURITY DIFFUSION LAYER

(71) Applicants: Toshiro Morita, Kawasaki-shi (JP); Takashi Kamizono, Kawasaki-shi (JP); Tadashi Miyagi, Kawasaki-shi (JP)

(72) Inventors: Toshiro Morita, Kawasaki-shi (JP); Takashi Kamizono, Kawasaki-shi (JP); Tadashi Miyagi, Kawasaki-shi (JP)

(73) Assignee: TOKYO OHKA KOGYO CO., LTD., Kawasaki-shi (JP)

(21) Appl. No.: 13/808,371

(22) PCT Filed: Jul. 6, 2011
(86) PCT No.: PCT/JP2011/003880

§ 371 Date: Jan. 4, 2013

(30) Foreign Application Priority Data
Jul. 9, 2010 (JP) 2010-157167

(51) Int. Cl. H01L 31/18

(52) U.S. Cl. CPC H01L 31/18
USPC 438/57; 252/512; 252/513

(57) ABSTRACT

Provided is a diffusing agent composition used for the printing of a dopant component on a semiconductor substrate, the diffusing agent composition including a silicon compound (A), a dopant component (B), and a non-dopant metal component (C). Among these components, the content of Na contained as the non-dopant metal component (C) is less than 60 ppb relative to the total amount of the composition.

### FIELD OF THE INVENTION

The present invention relates to a diffusing agent composition and a method for forming an impurity diffusion layer.

### DESCRIPTION OF THE RELATED ART

In the conventional production processes for solar cells, in the case of forming, for example, an N-type or P-type impurity diffusion layer in a semiconductor substrate, the formation has been carried out by a method of applying an impurity diffusing agent containing an N-type or P-type dopant component (also referred to as an impurity diffusing component) on the semiconductor substrate, and diffusing the impurity diffusing agent into the semiconductor substrate by subjecting the semiconductor substrate to a heat treatment by using a diffusion furnace or the like.

Furthermore, in recent years, there has been proposed, in order to form a solar cell having higher efficiency, a method of patterning a diffusing agent on the surface of a semiconductor substrate by using an inkjet system (see, for example, Japanese Patent Application Laid-Open Nos. 2003-168810, 2003-332606, and 2006-156646). When an inkjet system is used, since patterning is achieved by selectively ejecting a diffusing agent through an inkjet nozzle into an impurity diffusion layer-forming region without using a mask, a complicated process is not needed as compared with conventional photolithographic methods and the like, and a pattern can be easily formed while the amount of the liquid used is reduced.

### CITATION LIST

### Patent Document

Patent Document 1: JP 2003-168810 A
Patent Document 2: JP 2003-332606 A
Patent Document 3: JP 2006-156646 A

### DISCLOSURE OF THE INVENTION

### Problems to be Solved by the Invention

When an impurity diffusion layer is formed in a semiconductor substrate for solar cells by using a diffusing agent containing an N-type or P-type dopant component, there is a problem that the metal components other than the dopant component that are contained in the diffusing agent cause a decrease in the diffusion performance of the diffusing agent, and the electrical characteristics of the semiconductor substrate are deteriorated.

The present invention was made in view of such problems, and an object of the present invention is to provide a diffusing agent composition which can promote a further enhancement of electrical characteristics when an impurity diffusion layer is formed in a semiconductor substrate for solar cells, by enhancing the diffusing capacity.

### Means for Solving the Problems

A first aspect of the present invention provides a diffusing agent. The diffusing agent composition used for diffusion of a dopant component into a semiconductor substrate includes: a silicon compound (A); a dopant component (B); and a non-dopant metal component (C), wherein a content of Na contained as the non-dopant metal component (C) is less than 60 ppb relative to a total amount of the composition.

When the diffusing agent composition according to this embodiment is used, a further enhancement of electrical characteristics can be promoted when an impurity diffusion layer is formed in a semiconductor substrate for solar cells.

A second aspect of the present invention provides a method for forming an impurity diffusion layer. The method for forming an impurity diffusion layer includes the steps of: forming a diffusion layer by applying the above-described diffusing agent composition on a semiconductor substrate; and diffusing a dopant component (B) in the diffusing agent composition into the semiconductor substrate.

According to this embodiment, an impurity diffusion layer having enhanced electrical characteristics can be formed.

### EFFECT OF THE INVENTION

According to the present invention, a further enhancement of electrical characteristics can be promoted when an impurity diffusion layer is formed in a semiconductor substrate that is used in solar cells and the like.

### BRIEF DESCRIPTION OF THE DRAWINGS

FIGS. 1A to 1D are process cross-sectional diagrams intended to illustrate a method for producing a solar cell, which includes the method for forming an impurity diffusion layer according to an exemplary embodiment of the invention; and

FIGS. 2A to 2D are process cross-sectional diagrams intended to illustrate a method for producing a solar cell, which includes the method for forming an impurity diffusion layer according to an exemplary embodiment of the invention.

### BEST MODE FOR CARRYING OUT THE INVENTION

The present invention will be described hereinbelow on the basis of preferred embodiments with reference to the drawings. Meanwhile, the same symbols will be assigned to the same constituent elements throughout the drawings, and explanations will not be repeated appropriately.

The diffusing agent composition according to an exemplary embodiment is used for the diffusion of a dopant into a semiconductor substrate. The semiconductor substrate can be used as a substrate for solar cells. The relevant diffusing agent composition contains a silicon compound (A), a dopant component (B), and a non-dopant metal component (C). The various components of the diffusing agent composition of the present exemplary embodiment will be described in detail hereinbelow.

(A) Silicon Compound

The silicon compound (A) is at least one selected from the group consisting of SiO₂ fine particles, and a reaction product obtainable by hydrolyzing an alkoxysilane represented by the following formula (1) (hereinafter, appropriately referred to as a hydrolysate of an alkoxysilane). The SiO₂ fine particles and the hydrolysate of an alkoxysilane will be respectively described below.

<Hydrolysate of Alkoxysilane>

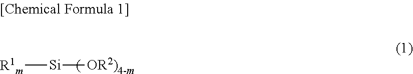

wherein in the formula (1), R¹ represents a hydrogen atom, an alkyl group, or an aryl group such as a phenyl group; R² represents an alkyl group or an aryl group such as a phenyl group; m represents an integer of 0, 1 or 2; and when there are plural R¹'s, the plural R¹'s may be identical with or different from each other, and when there are plural (OR²)'s, the plural (OR²)'s may be identical with or different from each other.

When R¹ is an alkyl group, a linear or branched alkyl group having 1 to 20 carbon atoms is preferred, and a linear or branched alkyl group having 1 to 4 carbon atoms is more preferred.

When R² is an alkyl group, a linear or branched alkyl group having 1 to 5 carbon atoms is preferred, and in view of the rate of hydrolysis, an alkyl group having 1 or 2 carbon atoms is more preferred. m is preferably 0.

A silane compound (i) in the case where m in the formula (1) is 0, is represented by the following formula (II).

Si(OR⁵¹)a(OR⁵²)b(OR⁵³)c(OR⁵⁴)d (II)

wherein in the formula (II), R⁵¹, R⁵², R⁵³ and R⁵⁴ each independently represent any of the same alkyl group and the same aryl group such as a phenyl group, as those represented by R²; and a, b, c and d represent integers that satisfy the conditions of 0≦a≦4, 0≦b≦4, 0≦c≦4, 0≦d≦4, and a+b+c+d=4.

A silane compound (ii) in the case where m in the formula (1) is 1, is represented by the following formula (III).

R⁶⁵Si(OR⁶⁶)e(OR⁶⁷)f(OR⁶⁸)g (III)

wherein in the formula (III), R⁶⁵ represents any of the same hydrogen atom, alkyl group, and aryl group such as a phenyl group, as those represented by R; R⁶⁶, R⁶⁷ and R⁶⁸ each independently represent any of the same alkyl group and the same aryl group such as a phenyl group, as those represented by R²; and e, f, and g are integers that satisfy the conditions of 0≦e≦3, 0≦f≦3, 0≦g≦3, and e+f+g=3.

A silane compound (iii) in the case where m in the formula (1) is 2, is represented by the following formula (IV).

R⁷⁰R⁷¹Si(OR⁷²)h(OR⁷³)ᵢ (IV)

wherein in the formula (IV), R⁷⁰ and R⁷¹ each represent any of the same hydrogen atom, alkyl group and aryl group such as a phenyl group, as those represented by R¹, provided that at least one of R⁷⁰ and R⁷¹ represents an alkyl group or an aryl group such as a phenyl group; R⁷² and R⁷³ each independently represent any of the same alkyl group and aryl group such as a phenyl group, as those represented by R²; and h and i are integers that satisfy the conditions of 0≦h≦2, 0≦i≦2, and h+i=2.

Specific examples of the silane compound (i) include tetraalkoxysilanes such as tetramethoxysilane, tetraethoxysilane, tetrapropoxysilane, tetrabutoxysilane, tetrapentyloxysilane, tetraphenyloxysilane, trimethoxymonoethoxysilane, dimethoxydiethoxysilane, triethoxymonomethoxysilane, trimethoxymonopropoxysilane, monomethoxytributoxysilane, monomethoxytripentyloxysilane, monomethoxytriphenyloxysilane, dimethoxydipropoxysilane, tripropoxymonomethoxysilane, trimethoxymonobutoxysilane, dimethoxydibutoxysilane, triethoxymonopropoxysilane, diethoxydipropoxysilane, tributoxymonopropoxysilane, dimethoxymonoethoxymonobutoxysilane, diethoxymonomethoxymonobutoxysilane, diethoxymonopropoxymonobutoxysilane, dipropoxymonomethoxymonoethoxysilane, dipropoxymonomethoxymonobutoxysilane, dipropoxymonoethoxymonobutoxysilane, dibutoxymonomethoxymonoethoxysilane, dibutoxymonoethoxymonopropoxysilane, and monomethoxymonoethoxymonopropoxymonobutoxysilane. Among them, tetramethoxysilane and tetraethoxysilane are preferred.

Specific examples of the silane compound (ii) include phenyltrimethoxysilane, phenyltriethoxysilane, methyltrimethoxysilane, methyltriethoxysilane, methyltripropoxysilane, methyltripentyloxysilane, ethyltrimethoxysilane, ethyltripropoxysilane, ethyltripentyloxysilane, ethyltriphenyloxysilane, propyltrimethoxysilane, propyltriethoxysilane, propyltripentyloxysilane, propyltriphenyloxysilane, butyltrimethoxysilane, butyltriethoxysilane, butyltripropoxysilane, butyltripentyloxysilane, butyltriphenyloxysilane, methylmonomethoxydiethoxysilane, ethylmonomethoxydiethoxysilane, propylmonomethoxydiethoxysilane, butylmonomethoxydiethoxysilane, methylmonomethoxydipropoxysilane, methylmonomethoxydipentyloxysilane, methylmonomethoxydiphenyloxysilane, ethylmonomethoxydipropoxysilane, ethylmonomethoxydipentyloxysilane, ethylmonomethoxydiphenyloxysilane, propylmonomethoxydipropoxysilane, propylmonomethoxydipentyloxysilane, propylmonomethoxydiphenyloxysilane, butylmonomethoxydipropoxysilane, butylmonomethoxydipentyloxysilane, butylmonomethoxydiphenyloxysilane, methylmethoxyethoxypropoxysilane, propylmethoxyethoxypropoxysilane, butylmethoxyethoxypropoxysilane, methylmonomethoxymonoethoxymonobutoxysilane, ethylmonomethoxymonoethoxymonobutoxysilane, propylmonomethoxymonoethoxymonobutoxysilane, and butylmonomethoxymonoethoxymonobutoxysilane. Among them, methyltrialkoxysilanes (particularly, methyltrimethoxysilane and methyltriethoxysilane), phenyltrimethoxysilane, and phenyltriethoxysilane are preferred.

Specific examples of the silane compound (iii) include methyldimethoxysilane, methylmethoxyethoxysilane, methyldiethoxysilane, methylmethoxypropoxysilane, methylmethoxypentyloxysilane, methylmethoxyphenyloxysilane, ethyldipropoxysilane, ethylmethoxypropoxysilane, ethyldipentyloxysilane, ethyldiphenyloxysilane, propyldimethoxysilane, propylmethoxyethoxysilane, propylethoxypropoxysilane, propyldiethoxysilane, propyldipentyloxysilane, propyldiphenyloxysilane, butyldimethoxysilane, butylmethoxyethoxysilane, butyldiethoxysilane, butylethoxypropoxysilane, butyldipropoxysilane, butylmethyldipentyloxysilane, butylmethyldiphenyloxysilane, dimethyldimethoxysilane, dimethylmethoxyethoxysilane, dimethyldiethoxysilane, dimethyldipentyloxysilane, dimethyldiphenyloxysilane, dimethylethoxypropoxysilane, dimethyldipropoxysilane, diethyldimethoxysilane, diethylmethoxypropoxysilane, diethyldiethoxysilane, diethylethoxypropoxysilane, dipropyldimethoxysilane, dipropyldiethoxysilane, dipropyldipentyloxysilane, dipropyldiphenyloxysilane, dibutyldimethoxysilane, dibutyldiethoxysilane, dibutyldipropoxysilane, dibutylmethoxypentyloxysilane, dibutylmethoxyphenyloxysilane, methylethyldimethoxysilane, methylethyldiethoxysilane, methylethyldipropoxysilane, methylethyldipentyloxysilane, methylethyldiphenyloxysilane, methylpropyldimethoxysilane, methylpropyldiethoxysilane, methylbutyldimethoxysilane, methylbutyldiethoxysilane, methylbutyldipropoxysilane, methylethylethoxypropoxysilane, ethylpropyldimethoxysilane, ethylpropylmethoxyethoxysilane, dipropyldimethoxysilane, dipropylmethoxyethoxysilane, propylbutyldimethoxysilane, propylbutyldiethoxysilane, dibutylmethoxyethoxysilane, dibutylmethoxypropoxysilane, and dibutylethoxypropoxysilane. Among them, methyldimethoxysilane and methyldiethoxysilane are preferred.

The hydrolysate can be produced by, for example, a method of hydrolyzing one kind or two or more kinds selected from the alkoxysilanes (i) to (iii) in the presence of an acid catalyst, water, and an organic solvent.

As the acid catalyst, organic acids and inorganic acids can all be used. Examples of the inorganic acids that can be used include sulfuric acid, phosphoric acid, nitric acid, and hydrochloric acid, and among them, phosphoric acid and nitric acid are suitable. Examples of the organic acids that can be used include carboxylic acids such as formic acid, oxalic acid, fumaric acid, maleic acid, glacial acetic acid, acetic anhydride, propionic acid, and n-butyric acid; and organic acids having sulfur-containing acid residues. Examples of the organic acids having sulfur-containing acid residues include organic sulfonic acids, and esterification products thereof include organic sulfuric acid esters and organic sulfurous acid esters. Among these, organic sulfonic acids in particular, for example, compounds represented by the following formula (5) are preferred.

R¹³—X (5)

wherein in the formula (5), R¹³ represents a hydrocarbon group which may be substituted; and X represents a sulfonic acid group.

In the formula (5), the hydrocarbon group for R¹³ is preferably a hydrocarbon group having 1 to 20 carbon atoms. This hydrocarbon group may be a saturated group or an unsaturated group, and may be any of linear, branched and cyclic groups. When the hydrocarbon group of R¹³ is cyclic, for example, an aromatic hydrocarbon group such as a phenyl group, a naphthyl group, or an anthryl group is preferred, and among them, a phenyl group is preferred. The aromatic ring in this aromatic hydrocarbon group may have one or plural hydrocarbon groups each having 1 to 20 carbon atoms may be bonded thereto as substituents. The hydrocarbon group as the substituent on the aromatic ring may be a saturated group or an unsaturated group, and may be any of linear, branched and cyclic groups. Furthermore, the hydrocarbon group for R¹³ may have one or plural substituents, and examples of these substituents include a halogen atom such as a fluorine atom, a sulfonic acid group, a carboxyl group, a hydroxyl group, an amino group, and a cyano group.

The acid catalyst acts as a catalyst when an alkoxysilane is hydrolyzed in the presence of water, and the amount of the acid catalyst to be used is preferably adjusted such that the concentration of the acid catalyst in the reaction system of the hydrolysis reaction is in the range of 1 ppm to 1000 ppm, and particularly 5 ppm to 800 ppm. Regarding the amount of water added, since the hydrolysis ratio of a siloxane polymer varies with the amount of water added, the amount of water to be added can be determined in accordance with the hydrolysis ratio intended to be obtained.

Examples of the organic solvent in the reaction system of a hydrolysis reaction include monohydric alcohols such as methanol, ethanol, propanol, isopropanol (IPA), and n-butanol; alkylcarboxylic acid esters such as methyl 3-methoxypropionate and ethyl 3 ethoxypropionate; polyhydric alcohols such as ethylene glycol, diethylene glycol, propylene glycol, glycerin, trimethylolpropane, and hexanetriol; monoethers of polyhydric alcohols, such as ethylene glycolmonomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monopropyl ether, diethylene glycol monobutyl ether, propylene glycol monomethyl ether, propylene glycol monoethyl ether, propylene glycol monopropyl ether, and propylene glycol monobutyl ether, or monoacetates thereof; esters such as methyl acetate, ethyl acetate, and butyl acetate; ketones such as acetone, methyl ethyl ketone, and methyl isoamyl ketone; and polyhydric alcohol ethers obtained by alkyl-etherifying all the hydroxyl groups of a polyhydric alcohol, such as ethylene glycol dimethyl ether, ethylene glycol diethyl ether, ethylene glycol dipropyl ether, ethylene glycol dibutyl ether, propylene glycol dimethyl ether, propylene glycol diethyl ether, diethyleneglycoldimethyl ether, diethyleneglycol diethyl ether, and diethylene glycol methyl ethyl ether. These organic solvents may be used singly, or two or more kinds may be used in combination.

When an alkoxysilane is subjected to a hydrolysis reaction in such a reaction system, a siloxane polymer may be obtained. The hydrolysis reaction is usually completed in about 5 hours to 100 hours, but in order to shorten the reaction time, it is preferable to heat the reaction system to a temperature range of no higher than 80° C.

After completion of the reaction, a reaction solution containing the siloxane polymer thus synthesized and the organic solvent used in the reaction, is obtained. The siloxane polymer can be obtained by separating the polymer from the organic solvent by a conventionally known method, and drying the polymer.

<SiO₂ Fine Particles>

The size of the SiO₂ fine particles is preferably such that the average particle size be 1 μm or less. Specific examples of the SiO₂ fine particles include fumed silica.

(B) Dopant Component

The dopant component (B) is a compound that is generally used as a dopant. The dopant component (B) is an N-type or P-type dopant component including a compound of an element of Group III (Group 13) or Group V (Group 15), and is capable of forming an N-type or P-type impurity diffusion layer (impurity diffusion region) within a semiconductor substrate. Examples of the compound of an element of Group V that is included in the dopant component (B), include P₂O₅, phosphoric acid esters such as dibutyl phosphate, tributyl phosphate, monoethyl phosphate, diethyl phosphate, triethyl phosphate, monopropyl phosphate, and dipropyl phosphate; Bi₂O₃, Sb(OCH₂CH₃)₃, SbCl₃, H₃AsO₄, and As(OC₄H₉)₃. The concentration of the dopant component (B) is appropriately adjusted in accordance with the layer thickness of the impurity diffusion layer formed in the semiconductor substrate, or the like. Meanwhile, examples of the dopant component (B) of Group III include B₂O₃, Al₂O₃, and gallium trichloride.

An important factor for the impurity diffusing effect is the balance between the amount of incorporation of the silicon compound (A) and the amount of incorporation of the dopant component (B), and particularly when the total weight of the amounts of incorporation of the silicon compound (A) and the dopant component (B) is designated as 100%, a satisfactory diffusing effect can be obtained when the ratio of the amount of incorporation of the silicon compound (A) is in the range of 50% to 90%, while the mixing ratio of the dopant component (B) is in the range of 10% to 50%.

(C) Non-Dopant Metal Component

The non-dopant metal component (C) is an unnecessary metal component that is contained in the diffusing agent composition as an impurity (contamination), for example, a residual metal component that is included in the raw materials such as the silicon compound (A) and is not completely removed by purification processes. Examples of the non-dopant metal component (C) include Na, Ca, Cu, Ni, and Cr. Among these non-dopant metal components (C), the content of Na is less than 60 ppb, and preferably less than 20 ppb, relative to the total amount of the composition.

The diffusing agent composition according to the present exemplary embodiment may further include, as other components, a surfactant (D), a solvent component (E), and additives. When the diffusing agent composition includes a surfactant (D), coatability, planarization properties, and spreadability can be enhanced, and the occurrence of coating unevenness of the diffusing agent composition layer that is formed after coating can be reduced. As such a surfactant (D) component, conventionally known compounds can be used, but a silicone-based surfactant is preferred. Furthermore, the surfactant (D) component is preferably included in an amount in the range of 100 ppm to 10,000 ppm by mass, preferably 300 ppm to 5,000 ppm by mass, and more preferably 500 ppm to 3,000 ppm by mass, relative to the total amount of the diffusing agent composition. Furthermore, it is more preferable if the amount of the surfactant component is 2,000 ppm by mass or less, because the detachability of the diffusing agent composition layer after a diffusion treatment is excellent. The compounds of the surfactant (D) component may be used singly, or may be used in combination.

There are no particular limitations on the solvent component (E), but examples thereof include alcohols such as methanol, ethanol, isopropanol, and butanol; ketones such as acetone, diethyl ketone, and methyl ethyl ketone; esters such as methyl acetate, ethyl acetate, and butyl acetate; polyhydric alcohols such as propylene glycol, glycerin, and dipropylene glycol; ethers such as dipropylene glycol dimethyl ether, ethylene glycol dimethyl ether, ethylene glycol diethyl ether, propylene glycol dimethyl ether, and propylene glycol diethyl ether; monoether-based glycols such as ethylene glycol monomethyl ether, ethylene glycol monoethyl ether, propylene glycolmonomethyl ether, propylene glycol monoethyl ether, and dipropylene glycol monomethyl ether; cyclic ethers such as tetrahydrofuran and dioxane; and ether-based esters such as propylene glycolmonomethyl ether acetate and propylene glycol monoethyl ether acetate.

The additives are added according to necessity, in order to regulate the characteristics such as viscosity of the diffusing agent composition. Examples of the additives include polypropylene glycol.

(Method for Forming Impurity Diffusion Layer and Method for Producing Solar Cell)

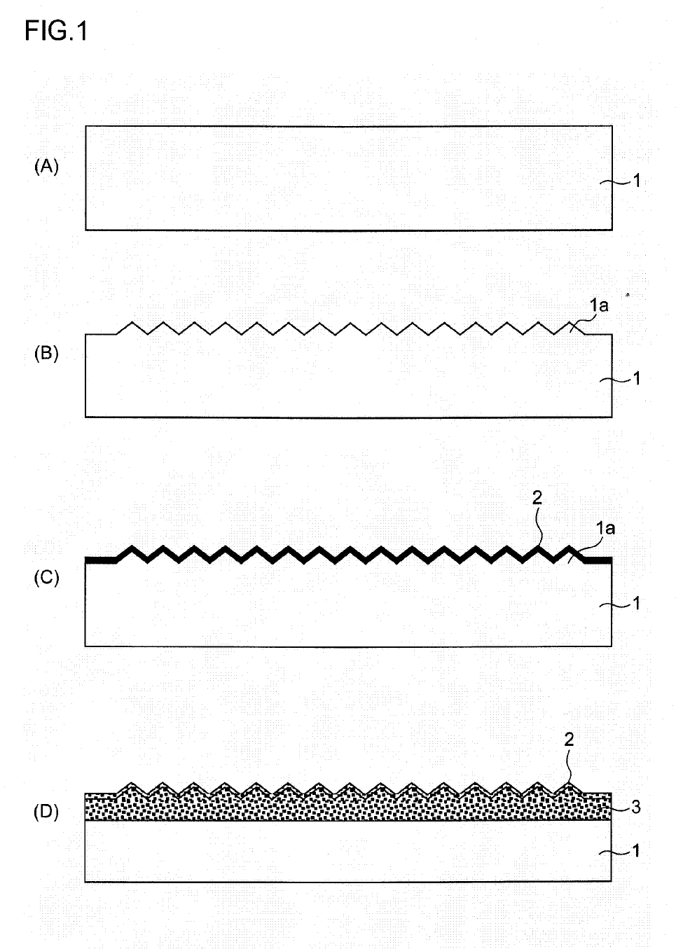

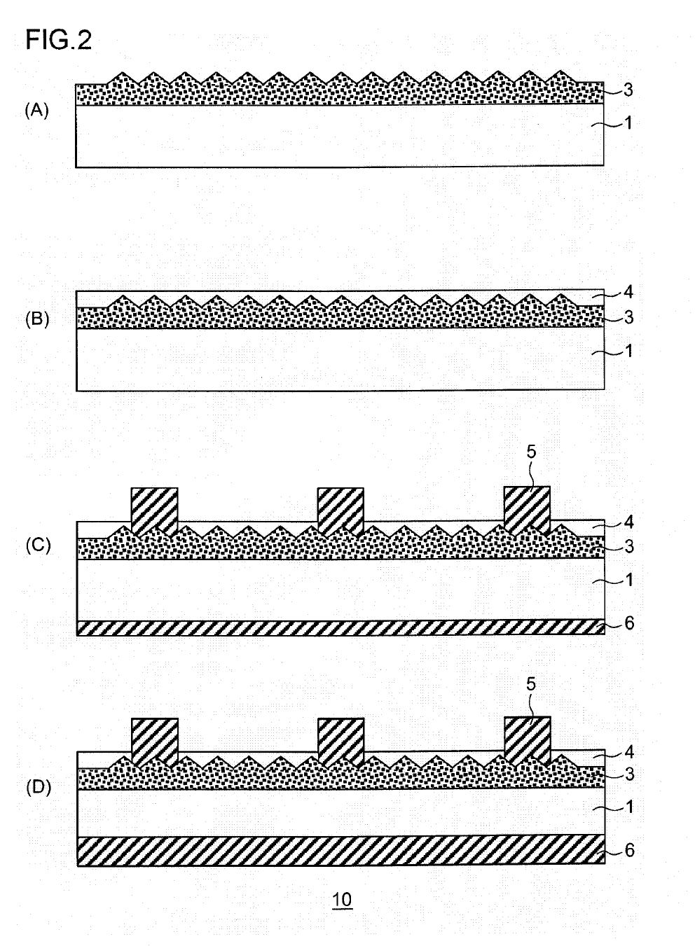

With reference to FIGS. 1A to 1D and FIGS. 2A to 2D, a method for forming an impurity diffusion layer, which includes a step of applying or printing the diffusing agent composition described above containing an N-type dopant component (B) on an N-type semiconductor substrate and thereby forming a pattern thereon; and a step of diffusing the dopant component (B) in the diffusing agent composition into the semiconductor substrate, and a method for producing a solar cell including a semiconductor substrate in which an impurity diffusion layer is formed by the foregoing method, will be described. FIGS. 1A to 1D and FIGS. 2A to 2D are process cross-sectional diagrams intended to illustrate a method for producing a solar cell, which includes the method for forming an impurity diffusion layer according to the exemplary embodiment.

First, as illustrated in FIG. 1A, an N-type semiconductor substrate 1 such as a silicon substrate is provided. As illustrated in FIG. 1B, a textured portion 1a having a fine concave-convex structure is formed on one of the principal surfaces of the semiconductor substrate 1, by using a well-known wet etching method. Reflection of light at the surface of the semiconductor substrate 1 is prevented by this textured portion 1a. Subsequently, as illustrated in FIG. 1C, the diffusing agent composition 2 containing a P-type dopant component (B) is applied on the principal surface of the semiconductor substrate 1 on the textured portion 1a side.

The diffusing agent composition 2 is applied on the surface of the semiconductor substrate 1 by a spin-on method. That is, the diffusing agent composition 2 is spin coated on the surface of the semiconductor substrate 1 by using any spin coating apparatus. An impurity diffusing agent layer is formed as such, and then the diffusing agent composition 2 thus applied is dried by using a well-known means such as an oven.

Next, as illustrated in FIG. 1D, the semiconductor substrate 1 on which the diffusing agent composition 2 is applied is placed in an electric furnace and baked. After the baking, the P-type dopant component (B) in the diffusing agent composition 2 is caused to diffuse from the surface of the semiconductor substrate 1 into the semiconductor substrate 1 in the electric furnace. Meanwhile, the semiconductor substrate 1 may also be heated by irradiation with a laser that is commonly used, instead of the electric furnace. In this manner, the P-type dopant component (B) diffuses in the semiconductor substrate 1, and a P-type impurity diffusion layer 3 is formed.

Next, as illustrated in FIG. 2A, the diffusing agent composition 2 is removed by a well-known etching method. Furthermore, as illustrated in FIG. 2B, a passivation film 4 formed from a silicon nitride film (SiN film) is formed on the principal surface of the semiconductor substrate 1 on the textured portion 1a side, by using a well-known chemical vapor deposition method (CVD method), for example, a plasma CVD method. This passivation film 4 also functions as an anti-reflection film.

Next, as illustrated in FIG. 2C, a front surface electrode 5 is patterned on the principal surface of the semiconductor substrate 1 on the passivation film 4 side, for example, by screen printing a silver (Ag) paste. The front surface electrode 5 is formed in a pattern so as to increase the efficiency of the solar cell. Furthermore, a back surface electrode 6 is formed on the other principal surface of the semiconductor substrate 1 by, for example, screen printing an aluminum (Al) paste.

Next, as illustrated in FIG. 2D, the semiconductor substrate 1 on which the back surface electrode 6 is formed is placed in an electric furnace and baked, and then the aluminum that forms the back surface electrode 6 is caused to diffuse into the semiconductor substrate 1. Thereby, the electrical resistance on the side of the back surface electrode 6 can be decreased. Through the process such as described above, a solar cell 10 according to the present exemplary embodiment can be produced.

The present invention is not intended to be limited to the exemplary embodiment described above, but modifications such as various design variations can also be applied based on the knowledge of those having ordinary skill in the art, and embodiments to which such modifications have been applied are also to be included in the scope of the present invention. New embodiments created by combinations of the exemplary embodiments described above and the following modifications exhibit both the effects of the exemplary embodiments and the effects of the modifications that are combined.

The diffusing agent composition according to the exemplary embodiment described above can also be employed by a printing method such as a spin-on method, a spray coating method, an inkjet printing method, a roll coating printing method, a screen printing method, a relief printing method, an intaglio printing method, or an offset printing method.

### EXAMPLES

Hereinafter, Examples of the present invention will be described, but these Examples are only for the purpose of suitably illustrating the present invention and are not intended to limit the present invention by any means.

(Diffusing Agent Composition)

Various components and contents thereof of the diffusing agent compositions of Examples 1 to 3 and Comparative Example 1 are presented in Table 1.

TABLE 1

| | | | | | | | Solvent | | |
|---|---|---|---|---|---|---|---|---|---|
| | Silicon compound (A) | | Dopant component (B) | | Surfactant (D) | | component | Additive | |
| | | Content | | Content | | Content | (E) | | Content |
| | Component | (wt %) | Component | (wt %) | Component | (ppm) | Component | Component | (wt %) |
| Comparative | Organosiloxane (a) | 18 | Dibutyl | 41.47 | Si-based | 1500 | DPGM | Polypropylene | 2 |
| Example 1 | | | phosphate | | surfactant | | | glycol | |
| Comparative | Organosiloxane (a) | 18 | Dibutyl | 41.47 | Si-based | 1500 | DPGM | Polypropylene | 2 |
| Example 2 | | | phosphate | | surfactant | | | glycol | |
| Comparative | Organosiloxane (a) | 18 | Dibutyl | 41.47 | Si-based | 1500 | DPGM | Polypropylene | 2 |
| Example 3 | | | phosphate | | surfactant | | | glycol | |
| Example 1 | Organosiloxane (a) | 18 | Dibutyl | 41.47 | Si-based | 1500 | DPGM | Polypropylene | 2 |
| | | | phosphate | | surfactant | | | glycol | |

In Table 1, the organosiloxane (a) is a silicon compound represented by the following formula.

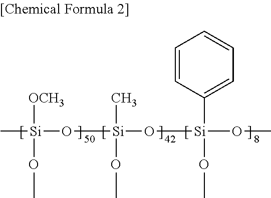

As the Si-based surfactant indicated in Table 1, SF8421EG (manufactured by Dow Corning Toray Co., Ltd.) was used. Also, the abbreviation described in Table 1 represents the following compound.

DPGM: Dipropylene glycol monomethyl ether

The non-dopant metal component (C) that is included in the diffusing agent compositions of Example 1 and Comparative Examples 1 to 3 were measured by using an atomic absorption spectrophotometer (Hitachi, Ltd., Z-2000). The measurement results for the content of the non-dopant metal component (C) are presented in Table 2. Meanwhile, the measurement limit of the measurement with the atomic absorption spectrophotometer (Hitachi, Ltd., Z-2000) is 20 ppb. In Table 2, the inequality symbol “<” indicates that the amount detected is less than the detection limit. Meanwhile, in Example 1 and Comparative Examples 1 to 3, dibutyl phosphate was used as the dopant component (B). The content of Na was regulated by adjusting the degree of purification of dibutyl phosphate.

### Evaluation of Sheet Resistance Value

For the respective diffusing agent compositions of Examples and Comparative Examples, an evaluation of the diffusion performance was carried out. Meanwhile, the diffusion performance was evaluated by measuring the sheet resistance value. In general, a smaller sheet resistance value leads to higher diffusing capacity. A specific technique for the evaluation of the sheet resistance value will be described below.

Each of the diffusing agent compositions of Example 1 and Comparative Examples 1 to 3 was applied on a P-type Si substrate (plane orientation <100>, resistivity 5 to 15Ω·cm) by a spin coating method. The thickness of the diffusing agent composition applied on the Si substrate was about 7000 Å. The Si substrate was prebaked for about one minute each at 100° C. and 200° C., and then was heated for 30 minutes at 950° C. in a nitrogen atmosphere by using a heating furnace (Koyo Thermo Systems Co., Ltd., VF-1000). Thereafter, the Si substrate was immersed in a 5% aqueous HF solution for 10 minutes, and thus the oxide film at the substrate surface was removed. Meanwhile, two samples were produced for each of Example 1 and Comparative Examples 1 to 3. For each of the samples, the sheet resistance values at five sites were measured by a four probe method (VR-70 manufactured by Kokusai Electric, Inc.), and the sheet resistance values at 10 points in total were obtained for each of Example 1 and Comparative Examples 1 to 3. Subsequently, the average value of the total 10 points was calculated. The average values of the sheet resistance values thus obtained are presented in Table 2.

TABLE 2

| | | | | | | Sheet |
|---|---|---|---|---|---|---|
| | Non-dopant metal component (C) <Content of | | | | | resistance |
| | various non-dopant metal components (wtppb)> | | | | | value |
| | Na | Ca | Cu | Ni | Cr | (Ω/sq) |
| Comparative | 1000 | <20 | <20 | <20 | <20 | 353.4 |
| Example 1 | | | | | | |
| Comparative | 100 | <20 | <20 | <20 | <20 | 307.4 |
| Example 2 | | | | | | |
| Comparative | 60 | <20 | <20 | <20 | <20 | 292.2 |
| Example 3 | | | | | | |
| Example 1 | <20 | <20 | <20 | <20 | <20 | 220.0 |

As indicated in Table 2, it was confirmed that as compared with Comparative Examples 1 to 3 where the content of Na contained as the non-dopant metal component (C) is 60 ppb to 1,000 ppb, in Example 1 where the content of Na contained as the non-dopant metal component (C) is less than 60 ppb, the sheet resistance value decreased rapidly. Since all of the elements other than Na were detected to a level lower than the detection limit, it is contemplated that the content of Na contributes significantly to an improvement of the sheet resistance value.

### DESCRIPTION OF REFERENCE NUMERALS

1 semiconductor substrate, 1a textured portion, 2 diffusing agent composition, 3 P-type impurity diffusion layer, 4 passivation film, 5 front surface electrode, 6 back surface electrode, 10 solar cell

### INDUSTRIAL APPLICABILITY

The present invention is applicable to the fields related to a diffusing agent composition and an impurity diffusion layer.

1. A diffusing agent composition used for diffusion of a dopant component into a semiconductor substrate, the composition comprising:
a silicon compound (A);
a dopant component (B); and
a non-dopant metal component (C), wherein
a content of Na contained as the non-dopant metal component (C) is less than 60 ppb relative to a total amount of the composition.

2. The diffusing agent composition according to claim 1, wherein
the dopant component (B) contains a compound of an element of Group III or an element of Group V.

3. The diffusing agent composition according to claim 1, wherein
the silicon compound (A) is at least one selected from the group consisting of SiO₂ fine particles, and a reaction product obtainable by hydrolyzing an alkoxysilane represented by the following formula (1): 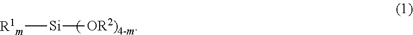
wherein R¹ represents a hydrogen atom, an alkyl group, or an aryl group; R² represents an alkyl group or an aryl group; m represents an integer of 0, 1, or 2; and when there are plural R¹'s, plural R¹'s may be the same or different, and when there are plural (OR²)'s, plural (OR²)'s may be the same or different.

4. The diffusing agent composition according to claim 1, further comprising a surfactant (D).

5. The diffusing agent composition according to claim 1, further comprising a solvent component (E).

6. A method for forming an impurity diffusion layer, comprising:
forming a diffusion layer by applying the diffusing agent composition according to claim 1 on a semiconductor substrate; and
diffusing a dopant component (B) in the diffusing agent composition into the semiconductor substrate.

7. The method for forming an impurity diffusion layer according to claim 6, wherein forming the diffusion layer includes forming a pattern by printing the diffusing agent composition.

8. The method for forming an impurity diffusion layer according to claim 6, wherein the semiconductor substrate is used in a solar cell.
